(19) United States
(12) Patent Application Publication
(10) Pub. No.: US 2019/0283284 A1
(43) Pub. Date: Sep. 19, 2019

(54) METHOD OF MANUFACTURING MICROCHANNEL

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Michihiko NISHIGAKI, Kawasaki Kanagawa (JP); Miyu NAGAI, Kawasaki Kanagawa (JP); Shouhei KOUSAI, Yokohama Kanagawa (JP); Yosuke AKIMOTO, Yokohama Kanagawa (JP); Kaita IMAI, Edogawa Tokyo (JP); Yutaka ONOZUKA, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 16/113,293

(22) Filed: Aug. 27, 2018

(30) Foreign Application Priority Data
Mar. 14, 2018 (JP) 2018-047146

(51) Int. Cl. B29C 41/20; B81C 1/00; B29C 41/00; B29C 41/42; B29C 35/08; B01L 3/00

(52) U.S. Cl. CPC B29C 41/20; B81C 1/00071; B29C 41/003; B29C 41/42; B29K 2083/00; B01L 3/502707; B81C 2201/034; B29C 2035/0827; B29C 35/0805

(57) ABSTRACT

According to one embodiment, a method of manufacturing a microchannel includes coating a silicone resin onto a mold corresponding to a microchannel and a first opening communicating with the microchannel, curing the silicone resin by light using a mask having a light shielding portion corresponding to the first opening, removing an uncured silicone resin, and releasing the cured silicone resin from the mold.

### CROSS-REFERENCE TO RELATED APPLICATIONS

This application is based upon and claims the benefit of priority from Japanese Patent Application No. 2018-047146, filed Mar. 14, 2018, the entire contents of which are incorporated herein by reference.

### FIELD

Embodiments described herein relate generally to a method of manufacturing a microchannel which is applied to a biosensor used, for example, in chemical or biochemical analysis and in which a specimen liquid or the like can move.

### BACKGROUND

Recently, various types of biosensors for inspecting cells, specimen liquids and the like in a microchannel have been developed. The microchannel includes an introduction hole for introducing a cell, a specimen liquid and the like and a discharge hole for discharging the cell, the specimen liquid and the like. When the microchannel is formed of a silicone resin such as poly-dimethyl-siloxane (PDMS) or the like, in the case in which the openings as a fine introduction hole and discharge hole are formed individually or collectively, there is a problem in that burrs occur in the openings.

### BRIEF DESCRIPTION OF THE DRAWINGS

FIG. 1 is a plane view showing an example of a biosensor according to a first embodiment;

FIG. 2 is a perspective view showing an example of a mold applied to the first embodiment;

FIG. 3A is a cross-sectional view taken along line III-III of FIG. 1, showing a method of manufacturing the biosensor according to the first embodiment;

FIG. 3B is a cross-sectional view showing a manufacturing process subsequent to FIG. 3A;

FIG. 3C is a cross-sectional view showing a manufacturing process subsequent to FIG. 3B;

FIG. 3D is a cross-sectional view showing a manufacturing process subsequent to FIG. 3C;

FIG. 3E is a cross-sectional view showing a manufacturing process subsequent to FIG. 3D;

FIG. 3F is a cross-sectional view showing a manufacturing process subsequent to FIG. 3E;

FIG. 4A is a cross-sectional view showing a method of manufacturing a biosensor according to a second embodiment;

FIG. 4B is a cross-sectional view showing a manufacturing process subsequent to FIG. 4A;

FIG. 4C is a cross-sectional view showing a manufacturing process subsequent to FIG. 4B;

FIG. 4D is a cross-sectional view showing a manufacturing process subsequent to FIG. 4C;

FIG. 4E is a cross-sectional view showing a manufacturing process subsequent to FIG. 4D;

FIG. 4F is a cross-sectional view showing a manufacturing process subsequent to FIG. 4E;

FIG. 4G is a cross-sectional view showing a manufacturing process subsequent to FIG. 4F;

FIG. 5A is a cross-sectional view showing a method of manufacturing a biosensor according to a third embodiment;

FIG. 5B is a cross-sectional view showing a manufacturing process subsequent to FIG. 5A;

FIG. 5C is a cross-sectional view showing a manufacturing process subsequent to FIG. 5B;

FIG. 5D is a cross-sectional view showing a manufacturing process subsequent to FIG. 5C;

FIG. 5E is a cross-sectional view showing a manufacturing process subsequent to FIG. 5D;

FIG. 5F is a cross-sectional view showing a manufacturing process subsequent to FIG. 5E;

FIG. 5G is a cross-sectional view showing a manufacturing process subsequent to FIG. 5F;

FIG. 5H is a cross-sectional view showing a manufacturing process subsequent to FIG. 5G;

FIG. 5I is a cross-sectional view showing a manufacturing process subsequent to FIG. 5H;

FIG. 5J is a cross-sectional view showing a manufacturing process subsequent to FIG. 5I;

FIG. 6A is a cross-sectional view showing a method of manufacturing a biosensor according to a fourth embodiment;

FIG. 6B is a cross-sectional view showing a manufacturing process subsequent to FIG. 6A;

FIG. 6C is a cross-sectional view showing a manufacturing process subsequent to FIG. 6B;

FIG. 6D is a cross-sectional view showing a manufacturing process subsequent to FIG. 6C;

FIG. 6E is a cross-sectional view showing a manufacturing process subsequent to FIG. 6D;

FIG. 6F is a cross-sectional view showing a manufacturing process subsequent to FIG. 6E;

FIG. 6G is a cross-sectional view showing a manufacturing process subsequent to FIG. 6F;

FIG. 6H is a cross-sectional view showing a manufacturing process subsequent to FIG. 6G;

FIG. 6I is a cross-sectional view showing a manufacturing process subsequent to FIG. 6H; and

FIG. 6J is a cross-sectional view showing a manufacturing process subsequent to FIG. 6I.

### DETAILED DESCRIPTION

In general, according to one embodiment, a method of manufacturing a microchannel includes: coating a silicone resin onto a mold corresponding to a microchannel and a first opening communicating with the microchannel and curing the silicone resin by light using a mask having a light shielding portion corresponding to the first opening, removing an uncured silicone resin, and releasing the cured silicone resin from the mold.

Hereinafter, the embodiments will be described with reference to the accompanying drawings. In the drawings, the same portions are denoted by the sane reference numerals. It should be noted that the drawings are schematic and thicknesses and dimensions are different from the actual ones. Further, the drawings include mutually different portions in terms of dimensional relationships and ratios.

### First Embodiment

FIG. 1 is a plane view showing an example of a biosensor 10 according to a first embodiment. FIG. 1 shows a case in which a plurality of biosensors 10 are provided on a semiconductor substrate 12.

The biosensor 10 includes a microchannel 11a formed of a silicone resin 11 such as PDMS or the like to be described below and a sensor 13 formed in the semiconductor substrate 12.

The silicone resin 11 has openings 11b and 11c for introducing cells or a fluid (hereinafter, also referred to as the specimen liquid) such as a specimen liquid or the like into the microchannel 11a and discharging the cells or fluid from the microchannel 11a.

The sensor 13 detects physical or chemical information of the specimen liquid. The sensor 13 can be changed depending on an object to be detected.

When the sensor 13 is an optical sensor, for example, it is possible to detect an intensity of fluorescence emitted from fluorescently stained cells contained in the specimen liquid flowing in the microchannel 11a using the photodiode as the sensor 13. Further, it is also possible to acquire an image of cells contained in the specimen liquid by using an image sensor as the sensor 13. In addition, it is possible to obtain pH and an ion concentration of liquids such as the specimen liquid or the like, for example, by using an ion sensitive field effect transistor (ISFET) as the sensor 13.

FIG. 1 shows a case in which the biosensors 10 are formed on the silicone resin 11 and the semiconductor substrate 12. However, the present invention is not limited thereto, but the number of biosensor 10, a shape of the microchannel 11a, the numbers and shapes of the openings 11b and 11c can be changed.

Further, in the following description, the microchannel 11a may be used as a general term including the openings 11b and 11c.

### Manufacturing Method

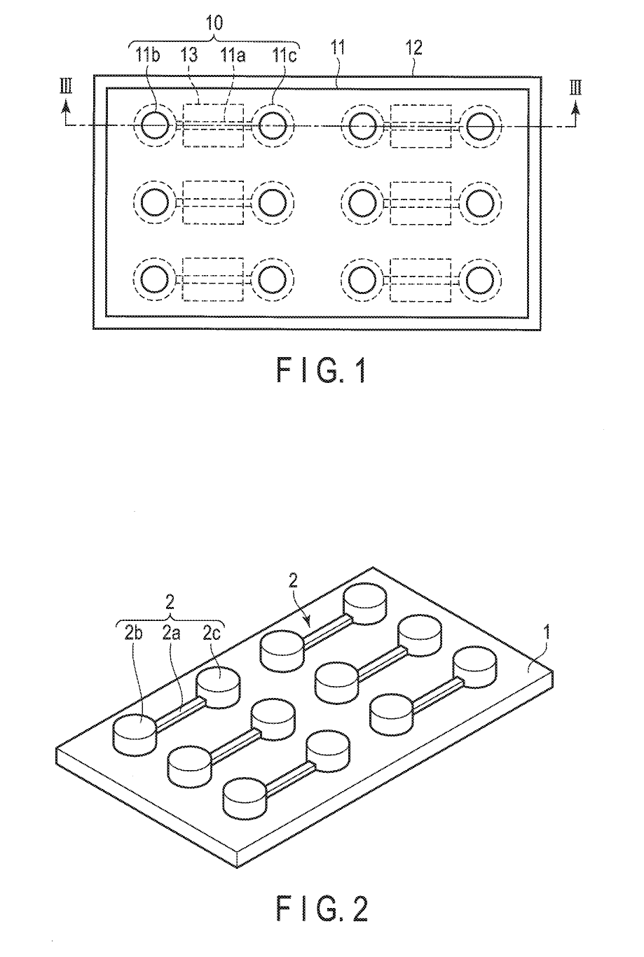

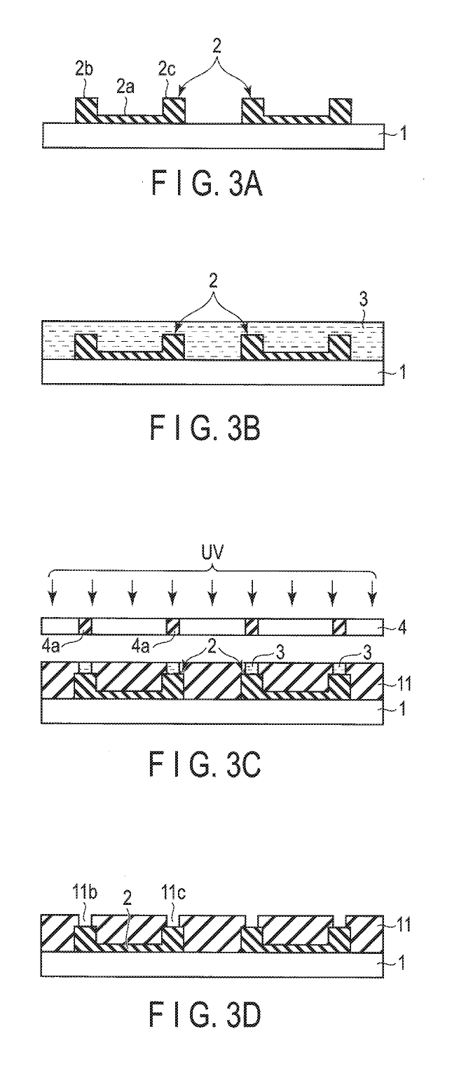

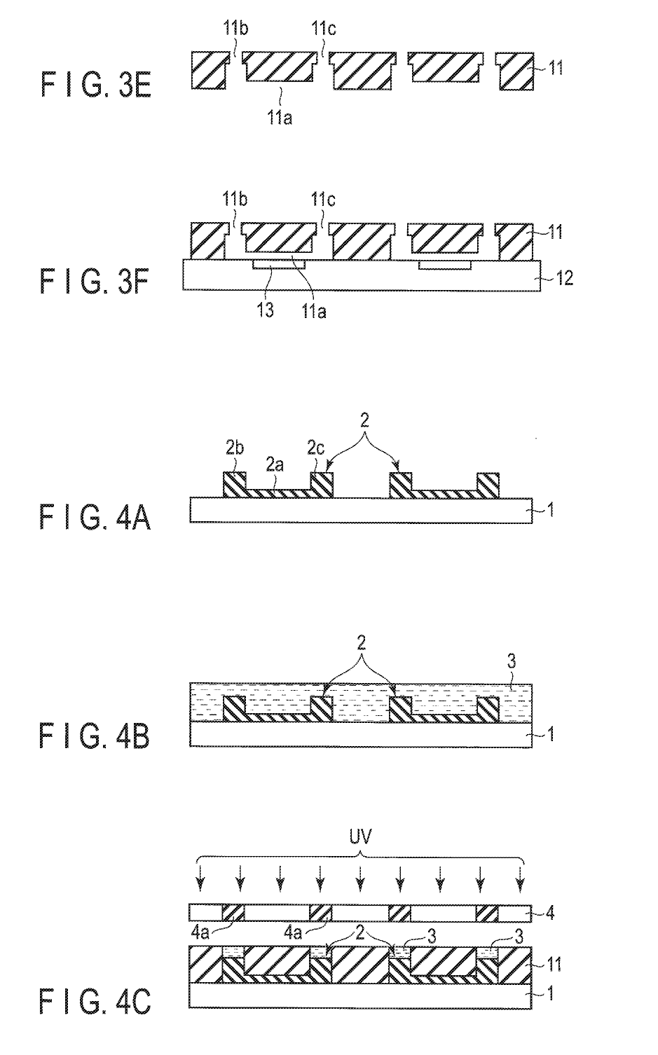

A method of manufacturing the biosensor 10 according to the first embodiment is described with reference to FIG. 2 and FIGS. 3A to 3F.

FIG. 2 shows an example of a mold applied to the biosensor 10 according to the first embodiment, and FIGS. 3A to 3F show a manufacturing process of the biosensor according to the first embodiment.

As shown in FIGS. 2 and 3A, first, a mold 2 is formed on a substrate 1. The mold 2 includes a first protrusion 2a corresponding to the microchannel 11a, a second protrusion 2b corresponding to the opening 11b, and a third protrusion 2c corresponding the opening 11c.

Further, heights of the second and third protrusions 2b and 2c may be the same as that of the first protrusion 2a. That is, the second and third protrusions 2b and 2c may be omitted.

As the substrate 1, for example, a silicon substrate, a glass substrate, a metal plate or the like used in manufacturing process of a semiconductor can be used.

The mold 2 can be formed as follows. First, for example, a liquid-state negative type thick photoresist can be coated on the substrate 1 by spin-coating. Next, the photoresist is exposed using a mask (not shown) corresponding to the shapes of the openings 11b and 11c of the microchannel 11a. Then, the mold 2 is formed by developing the photoresist.

Alternatively, a sneer, shaped negative thick photoresist is stacked on the substrate 1, and the photoresist is exposed using the mask (not shown). Then, the mold 2 can be formed by developing the photoresist.

The height (film thickness) of the microchannel 11a is different from the height (film thickness) of the openings 11b and 11c. For this reason, a lithography process may be performed several times depending on shapes of the microchannel 11a and the openings 11b and 11c. That is, the height of the first protrusion 2a or the second and third protrusions 2b and 2c of the mold 2 are adjusted to be equal to that of the microchannel 11a or the openings 11b and 11c by performing the lithography process several times.

Subsequently, as shown in FIG. 3B, a liquid-state silicone resin 3 is coaled on an entire surface of the substrate 1 so as to cover the mold 2. More specifically, the silicone resin 3 is spin-coated so that the entire surface of the substrate 1 is covered with the liquid-state silicone resin 3. A film thickness of the silicone resin 3 is larger than a height of a highest portion of the mold 2. Preferably, the film thickness of the silicone resin 3 is larger than a height of the mold 2 when the silicone resin 3 is cured and contracted.

The silicone resin 3 is, for example, a photocurable PDMS. More specifically, for example, the silicone resin 3 is a UV-activated heat-curable PDMS. However, a material of the silicone resin 3 is not limited as long as it can be exposed and cured by light and an uncured silicone resin can be removed by development. Further, for example, a material that does not scatter light, emits fluorescence, and is not toxic to cells in the specimen liquid can be used. Therefore, the material of the silicone resin 3 is not limited.

Further, after coating the silicone resin 3, it may also be possible to remove bubbles contained in the silicone resin 3 under a reduced pressure or to allow the silicone resin 3 to be surely filled between the molds 2.

As another method, the silicone resin 3 may be surely filled between the molds 2 by coating the silicone resin 3 under the reduced pressure and allowing the coated silicone resin 3 to stand in the air.

Further, in the case in which the silicone resin 3 is spin-coated, the thickness of the silicone resin 3 is thicker in an edge region as compared to a region in the vicinity of a central portion of the substrate 1. For this reason, the silicone resin 3 may also be allowed to have a uniform thickness over the entire surface of the substrate 1 by allowing the silicone resin 3 to stand after being coated.

In addition, after curing the silicone resin 3, in order to improve releasability from the mold 2, surfaces of the substrate 1 and the mold 2 may be coated with a fluorine-based polymer by plasma treatment using trifluoromethane or the like, or the surfaces of the substrate 1 and the mold 2 may also be coated with a metal such as Au or the like by deposition treatment or the like.

Then, as illustrated in FIG. 3C, ultraviolet (UV) light is irradiated onto the silicone resin 3 using a photomask 4, and heat is applied thereto, thereby curing the silicone resin 3. The photomask 4 includes a light shielding portion 4a corresponding to the second and third protrusions 2b and 2c of the mold 2. That is, the light shielding portion 4a is provided in regions corresponding to the openings 11b and 11c of the microchannel 11a shown in FIG. 1.

In FIG. 3C, reference numeral 11 denotes a cured silicone resin 3, and hereinafter, referred to as a cured silicone resin 11 or simply a silicone resin 11. In this case, the UV light is irradiated onto a region except for the regions corresponding to the openings 11b and 11c of the microchannel 11a, thereby thermally curing the silicone resin 3 in the region irradiated with the UV light. A wavelength and an exposure amount of the UV light irradiated onto the silicone resin 3, and a heat-curing temperature and time may be appropriately selected depending on the used silicone resin 3.

Further, the light shielding portion 4a is formed to correspond to the openings 11b and 11c of the microchannel 11a. However, the light shielding portion 4a may be formed to correspond to a region where the cured silicone resin 11 is not required, for example, a dicing line or the like.

Next, as shown in FIG. 3D, the uncured silicone resin 3 (except for the cured silicone resin 11) is removed by development, such that the openings 11b and 11c are formed. Any developer may be used as long as it can dissolve the silicone resin 3. For example, a solvent at least containing diisopropylamine, triethylamine, pentane, perfluorotributylamine, perfluorodecalin, xylene, ether, hexane, trichlorethylene, normal heptane, cyclohexane, dimethoxyethane, toluene, ethyl acetate, or methyl ethyl ketone preferably used. A development time is appropriately selected depending on the thickness of the silicone resin 3 or the kind of developer.

Next, as shown in FIG. 3E, the cured silicone resin 11 is released from the mold 2. The silicone resin 11 from which the mold 2 is removed has a concave structure substantially coinciding with the shape of the mold 2. In other words, the microchannel 11a communicating with the openings 11b and 11c is formed.

Finally, as shown in FIG. 3F, the semiconductor substrate 12 is bonded to a surface of the silicone resin 11 from which the mold 2 is removed. Therefore, the microchannel 11a is covered by the semiconductor substrate 12, and the microchannel 11a is completed. The semiconductor substrate 12 includes the sensor 13, and the sensor 13 is disposed to face the microchannel 11a.

Further, although the sensor 13 is disposed in the microchannel 11a, there is no need to dispose all the sensors 13 in the microchannel 11a, but some of the sensors 13 may be disposed in the microchannel 11a.

In addition, the cured silicone resin 11 and the semiconductor substrate 12 may be bonded to each other as follows. First, surfaces of the silicone resin 11 and the semiconductor substrate 12 are activated in oxygen plasma. Next, the silicone resin 11 is installed on a main surface of the semiconductor substrate 12, and a load and heat are applied thereto. Surface activation treatment conditions and load and heat application conditions are appropriately selected depending on the used silicone resin 3.

Further, although the surface activation treatment by the oxygen plasma is performed in the present embodiment, another bonding method except for a bonding method using surface activation treatment by the oxygen plasma may also be used as long as bonding strength enough to allowing the cured silicone resin 11 and the semiconductor substrate 12 to function as the microchannel is obtained.

Due to a structure shown in FIG. 3F, it is possible to detect physical or chemical information of the specimen liquid or the like by the sensor 13 disposed on the semiconductor substrate 12 by introducing the specimen liquid or the like, into the microchannel 11a, for example from the opening 11b.

### Effect of First Embodiment

According to the first embodiment, the silicone resin 3 is coated onto the mold 2 corresponding to the microchannel 11a and openings 11b and 11c provided on the substrate 1, the light is irradiated onto the silicone resin 3 using the mask 4 including the light shielding portion 4a corresponding to the openings 11b and 11c to cure the silicone resin 3, and the uncured silicone resin 3 and the mold 2 are sequentially removed, thereby forming the silicone resin 11 including the microchannel 11a and the openings 11b and 11c. For this reason, contrary to a case of forming the openings 11b and 11c using a drill or the like, smooth openings 11b and 11c can be formed without burrs at peripheral edges of the openings 11b and 11c.

Further, the microchannel 11a and the plurality of openings 11b and 11c communicating with the microchannel 11a can be formed at the same time. For this reason, a processing time can be shortened, and a process cost can be decreased.

### Second Embodiment

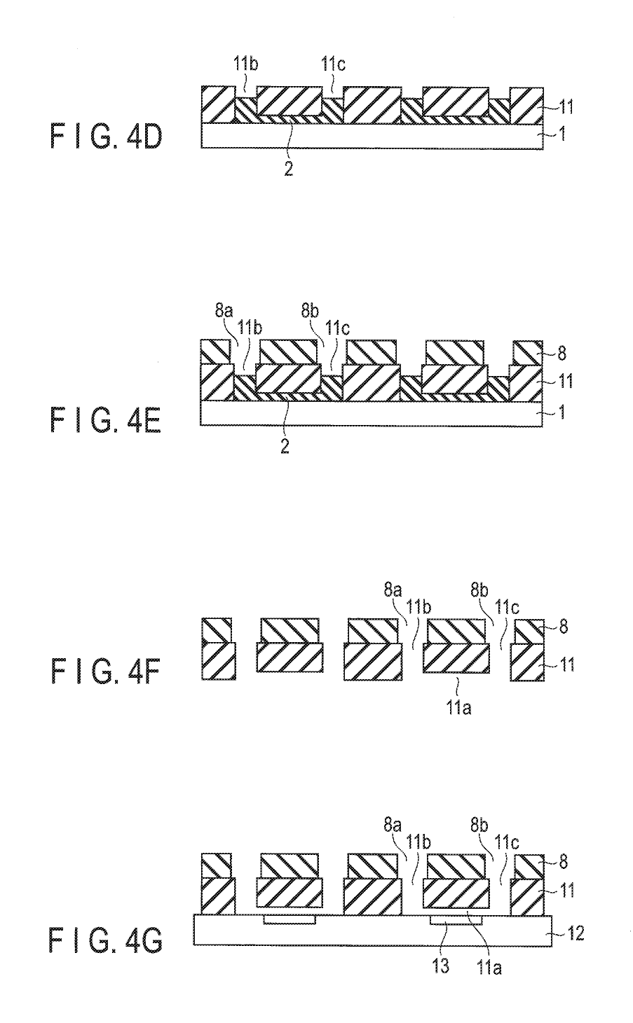

FIGS. 4A to 4G show a method of manufacturing a microchannel according to a second embodiment. In the second embodiment, which is a modified embodiment of the first embodiment, the timing of releasing a mold 2 is different from that in the first embodiment.

That is, in the first embodiment, the cured silicone resin 11 is bonded to the semiconductor substrate 12 after being removed from the mold 2. On the contrary, in the second embodiment, before a cured silicone resin 11 is removed from the mold 2, a support substrate 8 is bonded to the silicone resin 11. Thereafter, the silicone resin 11 is released from the mold 2.

In the second embodiment, since FIGS. 4A to 4D are similar to FIGS. 3A to 3D of the first embodiment, a detailed description thereof is omitted.

As shown in FIG. 4E, the support substrate 8 is bonded onto the cured silicone resin 11. The support substrate 8 includes openings 8a and 8b corresponding to openings 11b and 11c. A specimen liquid can be introduced and discharged from the openings 8a and 8b to the openings 11b and 11c by matching the openings 11b and 11c with the openings 8a and 8b at the time of bonding the support substrate 8 onto the silicone resin 11.

It is preferable that a size of the openings 8a and 8b of the support substrate 8 is equal to or larger than that of the openings 11b and 11c of the silicone resin 11, but is not limited as long as the specimen liquid or the like can be introduced into and discharged from a microchannel 11a.

As a material of the support substrate 8, a material capable of being bonded to the cured silicone resin 11 is preferable. For example, glass, silicon, plastics or the like can be used.

The support substrate 8 and the cured silicone resin 11 can be bonded to each other by the same method as the bonding method of the cured silicone resin 11 and the semiconductor substrate 12 described above. That is, for example, after surfaces of the silicone resin 11 and the support substrate 8 are activated in oxygen plasma, the support substrate 8 is installed on the silicone resin 11, and a load and heat are applied thereto, such that the support substrate 8 can be bonded onto the silicone resin 11. Alternatively, it is also possible to bond the support substrate 8 and the silicone resin 11 to each other using an adhesive. A bonding method of the support substrate 8 and the cured silicone resin 11 can be appropriately selected.

Further, the openings 8a and 8b of the support substrate 8 can be formed by a machining process using a sandblast machine or drill. In addition, when the material of the support substrate 8 is glass or silicon, the openings 8a and 8b can also be formed by etching. Further, when the material of the support substrate 8 is plastic, the openings 8a and 8b can also be formed by injection molding.

Next, as shown in FIG. 4F, the silicone resin 11 onto which the support substrate 8 is bonded is released from the mold 2 and a substrate 1. Since the silicone resin 11 is bonded to the entire surface of the support substrate 8, the silicone resin 11 can be surely released from the mold 2 and the substrate 1 at the same time by using the support substrate 8.

Finally, as shown in FIG. 4G, a surface of the silicone resin 11 from which the mold 2 is removed is bonded to a main surface of a semiconductor substrate 12 including a sensor 13. At the time of bonding, the same method as in the first embodiment can be used. In this manner, a microchannel 11a is completed, and a biosensor 10 in which a sensor 13 is disposed to correspond to the microchannel 11a is completed.

### Effect of Second Embodiment

According to the second embodiment, the same advantage as that of the first embodiment can be obtained. However, in the second embodiment, before the cured silicone resin 11 is released from the mold 2, the support substrate 8 is bonded to the silicone resin 11. For this reason, even in the case in which a thickness of the silicone resin 11 is thin, the cured silicone resin 21 can be surely released from the mold 2 and the substrate 1 at once.

Further, since the support substrate 8 is bonded onto the cured silicone resin 11, the support substrate 8 can collectively hold the silicone resin 11 including a plurality of microchannels 11a and openings 11b and 11c. For this reason, a handling property of the silicone resin 11 is good, and the semiconductor substrate 12 including the sensor 13 can be easily aligned with the silicone resin 11.

Specifically, since the support substrate 8 is bonded to the cured silicone resin 11, at the time of bonding the semiconductor substrate 12 and the cured silicone resin 11 to each other, a uniform load can be applied to the silicone resin 11. Therefore, a bonding yield of the semiconductor substrate 12 and the silicone resin 11 can be improved.

In addition, the support substrate 8 can improve mechanical strength of the cured silicone resin 11. For this reason, the support substrate 8 can serve as a protective layer of the silicone resin 11.

### Third Embodiment

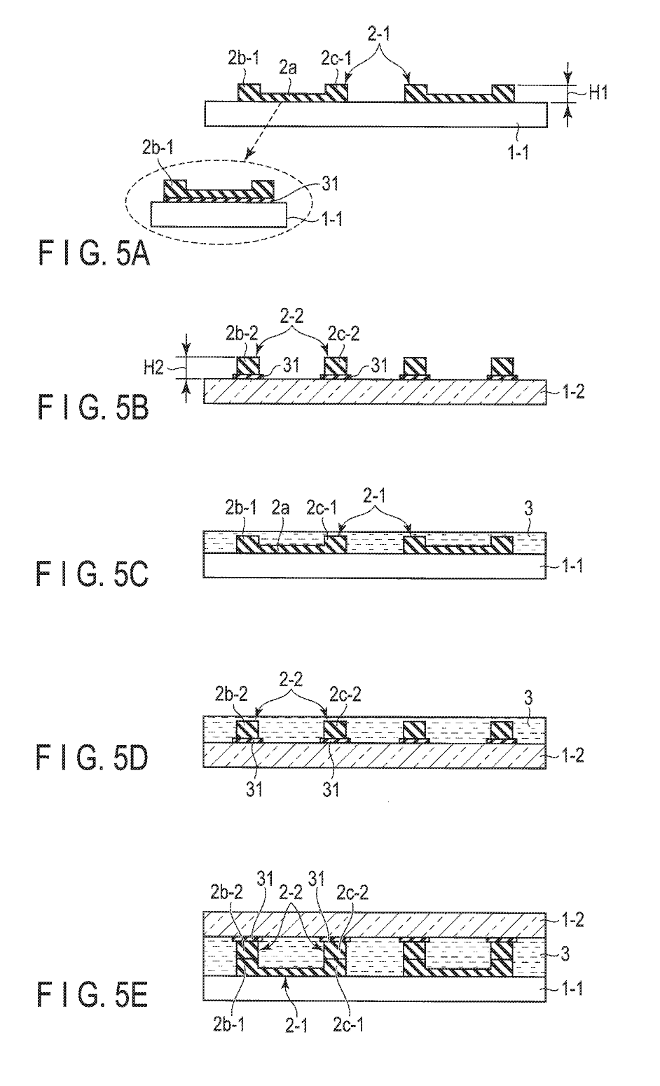

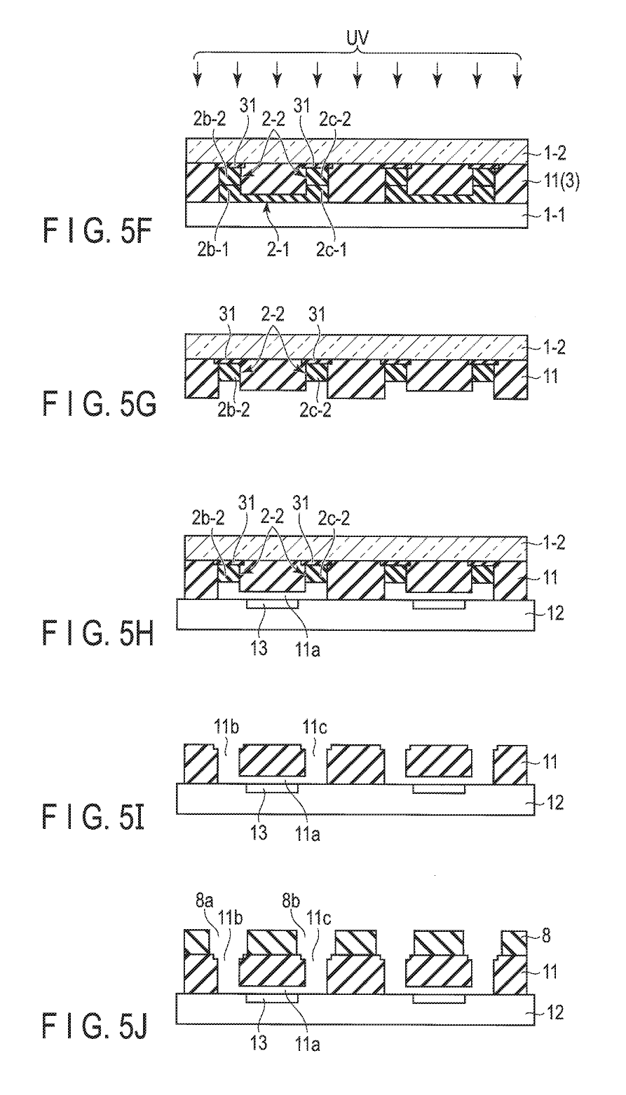

FIGS. 5A to 5J show a method of manufacturing a microchannel according to a third embodiment.

In the first and second embodiments, the microchannel is formed using a single mold. On the other hand, in the third embodiment, a microchannel and a plurality of openings are formed using two molds.

FIG. 5A shows a first mold 2-1, and FIG. 5B shows a second mold 2-2. The first mold 2-1 corresponds to the microchannel and a portion of the opening, and the second mold 2-2 corresponds to the other portion of the opening. The microchannel and the plurality of openings are formed using the first and second molds 2-1 and 2-2.

More specifically, as shown in FIG. 5A, the first mold 2-1 is formed on a first substrate 1-1. The first mold 2-1 includes a first protrusion 2a corresponding to the microchannel and second protrusions 2b-1 and 2c-1 corresponding to, for example, portions of two openings communicating with the microchannel. Materials of the first substrate 1-1 and the first mold 2-1 are the same as those in the first embodiment, and the first mold 2-1 is manufactured by the same method as that in the first embodiment.

As shown in FIG. 5B, the second mold 2-2 is formed on a second substrate 1-2. The second mold 2-2 includes third protrusions 2b-2 and 2c-2 corresponding to the other portions of two openings. A light shielding layer 31 is formed between the second substrate 1-2 and each of the third protrusions 2b-2 and 2c-2 as the second mold 2-2.

A size (diameter) of the light shielding layer 31 needs not necessarily to be larger than a size (diameter) of the third protrusions 2b-2 and 2c-2, but may be equal to or larger than that of the third protrusions 2b-2 and 2c-2.

As a material of the second substrate 1-2, a material capable of transmitting ultraviolet light irradiated in order to sure a silicone resin 3 to be described later is applied. More specifically, as the second substrate 1-2, a transparent material such as a glass plate is used.

The light shielding layer 31 may be disposed so as to partially or entirely cover a region in which the first and second molds 2-1 and 2-2 come in contact with each other as described later. Further, as shown in FIG. 5A, the light shielding layer 31 may also be provided between the first substrate 1-1 and the first mold 2-1.

As a material of the light shielding layer 31, a material capable of shielding UV light irradiated in order to cure the silicone resin 3 is preferable. For example, a metal material such as titanium, aluminum, platinum, gold or the like can be used. The light shielding layer 31 is formed in a desired pattern by etching after sputtering or depositing the metal on the second substrate 1-2 to form a thin film.

The third protrusions 2b-2 and 2c-2 as the second mold 2-2 are formed on the light shielding layer 31. A material and a method of manufacturing the second mold 2-2 are the same as those in the first embodiment.

A height H1 (film thickness) of the first mold 2-1 is slightly lower than a height H2 of the second mold 2-2. Therefore, releasability of the first mold 2-1 can be improved. A relationship between the height H1 of the first mold 2-1 and the height H2 of the second mold 2-2 is not limited thereto, but when the height H2 of the second mold 2-2 is lower than the height H1 of the first mold 2-1, releasability of the second mold 2-2 can be improved. Therefore, the height H1 of the first mold 2-1 and the height H2 of the second mold 2-2 may be set depending on, for example, a release sequence of the first and second molds 2-1 and 2-2.

In addition, the first mold 2-1 includes the second protrusions 2b-1 and 2c-1 corresponding to opening portions 11b and 11c but needs not necessarily to include the second protrusions 2b-1 and 2c-1. When the first mold 2-1 does not include the second protrusions 2b-1 and 2c-1, the height of the third protrusions 2b-2 and 2c-2 of the second mold 2-2 may be changed as needed.

Next, as shown in FIGS. 5C and 5D, a silicone resin 3 is coated so as to cover the first and second molds 2-1 and 2-2. Similarly to the first embodiment, the silicone resin 3 is a UV-activated heat-curable PDMS, and a liquid-state silicone resin 3 is coated onto entire surfaces of the first and second substrates 1-1 and 1-2 by spin-coating. It is preferable that a thickness of the silicone resin 3 is thicker than the heights of the first and second molds 2-1 and 2-2.

Subsequently, as shown in FIG. 5E, the second substrate 1-2 is stacked on the first substrate 1-1 coated with the silicone resin 3. That is, the third protrusions 2b-2 and 2c-2 as the second mold 2-2 are positioned to face the second protrusions 2b-1 and 2c-1 as the first mold 2-1 and stacked thereon.

Then, as shown in FIG. 5F, UV light is irradiated onto a rear surface of the second substrate 1-2 to apply heat thereto, thereby curing a silicone resin 11. The irradiated UV light is shielded by the light shielding layer 31. For this reason, the silicone resin 3 positioned directly below the light shielding layer 31, that is, the silicone resin 3 remaining in a region between the second protrusion 2b-1 and 2c-1 of the first mold 2-1 and -he third protrusion 2b-2 and 2c-2 of the second mold 2-2 is not exposed to the UV light and thus is not cured. In detail, when the first and second substrates 1-1 and 1-2 are warped and the height of the first mold 2-1 or the second mold 2-2 is not uniform, even though the first and second substrates 1-1 and 1-2 are stacked, the second protrusions 2b-1 and 2c-1 and the third protrusions 2b-2 and 2c-2 are not closely adhered to each other, such that the silicone resin 3 remains therebetween. The light shielding layer 31 serves to prevent the UV light from being irradiated onto the remaining silicone resin 3 and prevent the remaining silicone resin 3 from being cured.

Then, as shown in FIG. 5G, the cured silicone resin 11 is released from the first mold 2-1, such that the cured silicone resin 11 is in a state in which it remains on the second mold 2-2. Similarly in the first embodiment, the cured silicone resin 11 has a concave structure coinciding with the first mold 2-1. Here, an uncured silicone resin 3 is exposed to a surface of the second mold 2-2. The uncured silicone resin 3 is removed by a developer.

Here, when adhesion between the cured silicone resin 11 and the first mold 2-1 is higher than adhesion between the cured silicone resin 11 and the second mold 2-2, there is a possibility that the cured silicone resin 11 will not be removed even in the case of trying to remove the cured silicone resin 11 from the first mold 2-1. However, as described above, in the present embodiment, since the height of the first mold 2-1 is lower than the height of the second mold 2-2, the adhesion between the cured silicone resin 11 and the first mold 2-1 is lower than adhesion between the cured silicone resin 11 and the second mold 2-2. Therefore, the cured silicone resin 11 can be surely released from the first mold 2-1.

Next, as shown in FIG. 5H, a main surface of a semiconductor substrate 12 including a sensor 13 is bonded to a surface of the cured silicone resin 11 from which the first mold 2-1 is removed. In this case, the semiconductor substrate 12 and the silicone resin 11 are positioned so that the sensor 13 faces the microchannel 11a. The silicone resin 11 and the semiconductor substrate 12 are, similarly to the first embodiment, bonded to each other by performing surface activation treatment on the silicone resin 11 and the semiconductor substrate 12 in oxygen plasma and applying a pressure and heat to the stacked silicone resin 11 and semiconductor substrate 12.

Next, as shown in FIG. 5I, the cured silicone resin 11 is released from the second mold 2-2. The released silicone resin 11 includes a microchannel 11a and openings 11b and 11c communicating with the microchannel 11a.

Then, as shown in FIG. 5J, if necessary, a support substrate 8 is bonded onto the silicone resin 11. The support substrate 8 includes opening 8a and 8b corresponding to the openings 11b and 11c of the silicone resin 11.

Further, the light shielding layer 31 is disposed between the second substrate 1-2 and the second mold 2-2, but is not limited thereto. The light shielding layer 31 can be formed on a surface and a side surface of the second mold 2-2, and if necessary, the light shielding layer 31 may also be formed on the first substrate 1-1 and a surface and a side surface of the first mold 2-1. In this way, it is possible to further suppress the silicone resin 3 remaining in regions close to the first and second molds 2-1 and 2-2 from being undesirably cured by scattering of the UV light irradiated onto the silicone resin 3.

### Effect of Third Embodiment

According to the third embodiment, the liquid-state silicone resin 3 is applied onto the first substrate 1-1 including the first mold 2-1 corresponding to structures of the microchannel 11a and portions of the openings 11b and 11c and the second substrate 1-2 including the second mold 2-2 corresponding to structures of the remaining portions of the openings 11b and 11c, the first and second molds 2-1 and 2-2 are combined with each other, the silicone resin 3 is cured by the ultraviolet light, and then the first and second molds 2-1 and 2-2 are removed from the cured silicone resin 11. For this reason, the microchannel 11a and the openings 11b and 11c can be simultaneously formed.

Further, the silicone resin 3 remaining in a region in which the first and second molds 2-1 and 2-2 face each other is not exposed to the UV light but remains in an uncured state due to the light shielding layer 31, and the uncured silicone resin 3 is removed by a developer capable of dissolving the silicone resin 3. Therefore, similarly to the first embodiment, the openings 11b and 11c of which edges are smooth without burrs can be formed.

In addition, the height of the first mold 2-1 and the height of the second mold 2-2 are different from each other. For this reason, releasability between the first mold 2-1 and the second mold 2-2 can be appropriately set, and it is possible to form the first and second molds 2-1 and 2-2 in various shapes.

### Fourth Embodiment

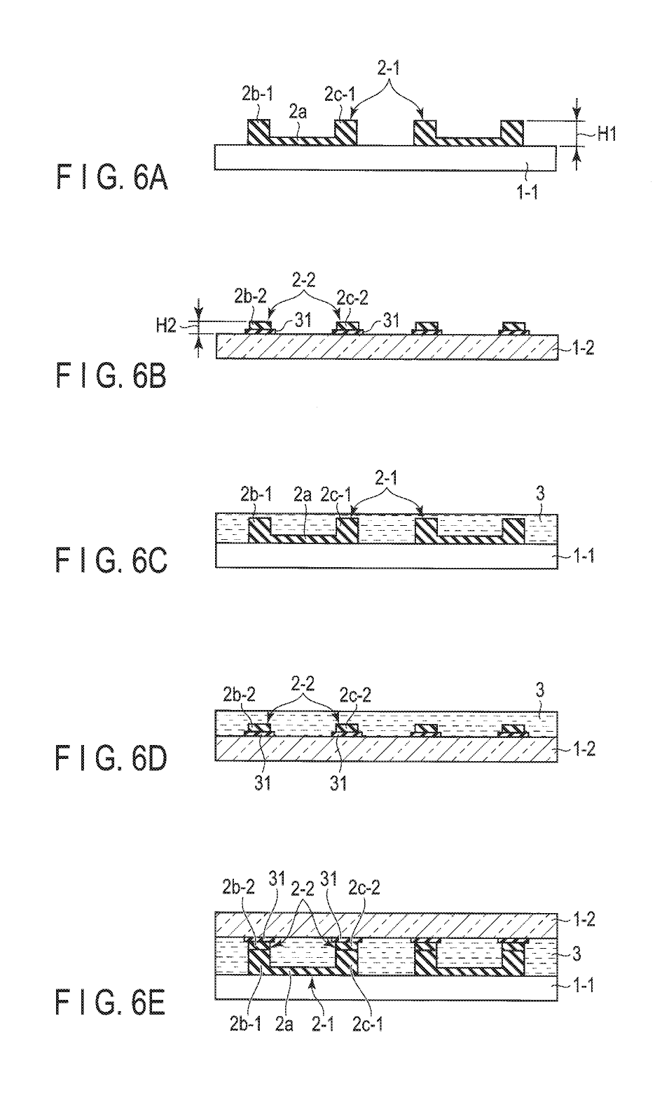

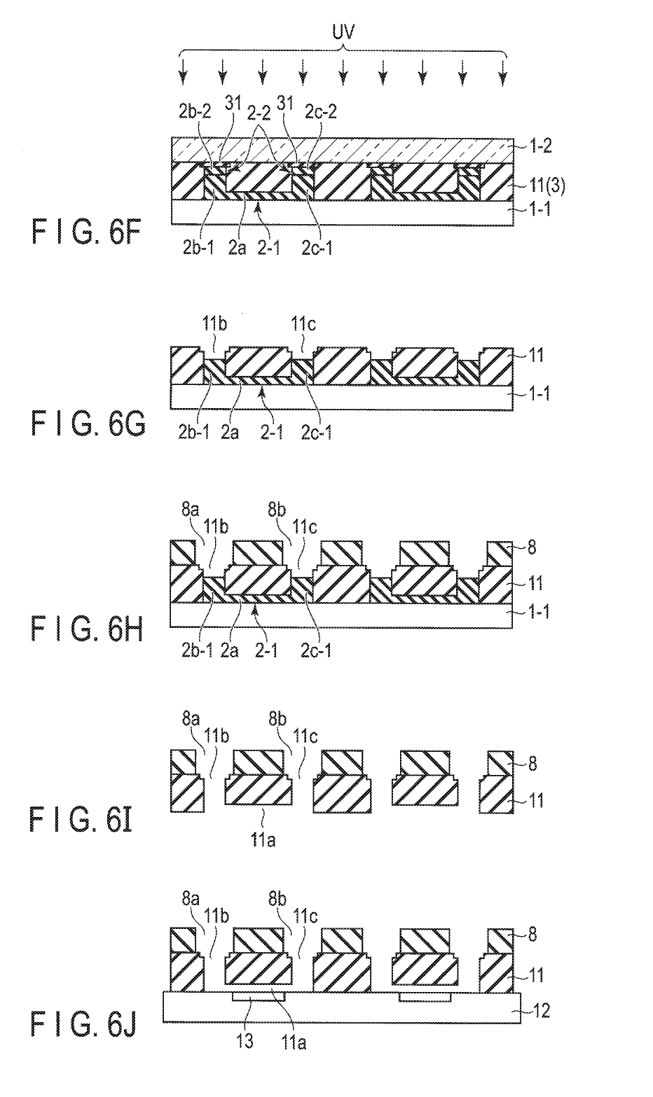

FIGS. 6A to 6J show a method of manufacturing a microchannel according to a fourth embodiment. In the fourth embodiment, which is a modified embodiment of the third embodiment, mainly the time of bonding a support substrate 8 to a cured silicone resin 11 is different from that in the third embodiment.

According to the fourth embodiment, since processes in FIGS. 6A to 6F are the same as those in the third embodiment, a detailed description thereof is omitted. However, as shown in FIGS. 6A and 6B, a relationship between height H1 of a first mold 2-1 and a height H2 of a second mold 2-2 is different from that in the third embodiment. That is, in the fourth embodiment, the height H2 of the second mold 2-2 is lower than the height H1 of the first mold 2-1. For this reason, according to the fourth embodiment, releasability of the second mold 2-2 is further improved as compared to the first mold 2-1.

As shown in FIG. 6F, the first mold 2-1 and the second mold 2-2 coated with a silicone resin 3 are combined and ultraviolet light is irradiated thereon from a second substrate 1-2 side, and then the silicone resin 3 is cured by heating. Thereafter, in the third embodiment, the first mold 2-1 is first released from the cured silicone resin 11, but in the fourth embodiment, the second mold 2-2 is released before the first mold 2-1 is released.

That is, as shown in FIG. 6G, the cured silicone resin 11 is released from the second mold 2-2. As described above, since the height H2 of the second mold 2-2 is lower than the height H1 of the first meld 2-1, the second mold 2-2 can be easily released from the cured silicone resin 11. Openings 11b and 11c are formed in the cured silicone resin 11 by removing the second mold 2-2.

Then, as shown in FIG. 6H, the support substrate 8 is bonded onto the cured silicone resin 11. A material and a bonding method of the support substrate 8 are the same as those in the second embodiment. The support substrate 8 includes opening 8a and 8b corresponding to the openings 11b and 11c formed in the silicone resin 11.

Next, as shown in FIG. 6I, the cured silicone resin 11 is released from the first mold 2-1. Since the silicone resin 11 is supported by the support substrate 8, the silicone resin 11 can be easily removed from the first mold 2-1. In this way, the cured silicone resin 11 including a microchannel 11a is exposed.

Thereafter, as shown in FIG. 6J, a semiconductor substrate 12 including a sensor 13 is bonded to the silicone resin 11 in which the microchannel 11a is formed. A bonding method is the same as that in the first embodiment.

### Effect of Fourth Embodiment

According to the fourth embodiment, the same advantage as that of the third embodiment can be obtained.

In addition, according to the fourth embodiment, the support substrate 8 is bonded to the cured silicone resin 11 in a state in which the first mold 2-1 is present in a region in which the microchannel 11a is formed. Therefore, as in the third embodiment, it is possible to apply a large load at the time of bonding as compared to the case in which the support substrate 8 is bonded to the silicone resin 11 cured in a hollow state in a region in which the microchannel 11a is formed. Therefore, occurrence of a bonding defect between the silicone resin 11 and the support substrate 8 can be suppressed.

Further, since the support, substrate 8 is bended to the cured silicone resin 11 in a state in which the first mold 2-1 is present in the region in which the microchannel 11a is formed, it is possible to prevent deformation of the microchannel 11a.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a microchannel, the method comprising:
coating a silicone resin onto a mold corresponding to a microchannel and a first opening communicating with the microchannel;
curing the silicone resin by light using a mask having a light shielding portion corresponding to the first opening;
removing an uncured silicone resin; and
releasing the cured silicone resin from the mold.

2. The method according to claim 1, wherein the silicone resin is coated in a thickness thicker than a height of the mold.

3. The method according to claim 2, wherein before the cured silicone resin is released from the mold, a support substrate including a second opening corresponding to the first opening of the microchannel is bonded to the cured silicone resin.

4. The method according to claim 3, wherein a substrate including a sensor is bonded to a surface of the silicone resin released from the mold.

5. A method of manufacturing a microchannel, the method comprising:
coating a silicone resin onto a first mold corresponding to a microchannel;
coating the silicone resin onto a second mold corresponding to a first opening to be communicated with the microchannel;
combining the first and second molds with each other;
curing the silicone resin by light;
releasing the cured silicone resin from one of the first and second molds;
removing an uncured silicone resin remaining on another of the first and second molds; and
releasing another of the first and second molds from the cured silicone resin.

6. The method according to claim 5, wherein a height of the first mold and a height of the second mold are different from each other.

7. The method according to claim 6, wherein the silicone resin is coated in a thickness thicker than the heights of the first and second molds.

8. The method according to claim 7, wherein
the first mold is formed on a first substrate,
the second mold is formed on a second substrate, and
a light shielding layer is formed at least between the first mold and the first substrate or between the second mold and the second substrate.

9. The method according to claim 8, wherein
before the cured silicone resin is released from the second mold, the cured silicone resin is released from the first mold, and
a third substrate including a sensor is bonded to a surface of the cured silicone resin from which the first mold is released.

10. The method according to claim 9, wherein after the cured silicone resin is released from the second mold, a support substrate including a second opening corresponding to the first opening is bonded to a surface of the cured silicone resin from which the second mold is released.

11. The method according to claim 8, wherein
before the cured silicone resin is released from the first mold, the cured silicone resin is released from the second mold, and
a support substrate including a second opening corresponding to the first opening is bonded to a surface of the cured silicone resin from which the second mold is released.

12. The method according to claim 11, wherein after the cured silicone resin is released from first mold, a third substrate including a sensor is bonded to a surface of the cured silicone resin from which the first mold is released.

13. The method according to claim 1, wherein the mold includes a first protrusion corresponding to the microchannel and a second protrusion corresponding to the first opening.

14. The method according to claim 1, wherein the silicone resin is cured by ultraviolet (UV) light.

15. The method according to claim 5, wherein the first mold includes a first protrusion corresponding to the microchannel and a second protrusion corresponding to the opening, and the second mold includes a third protrusion corresponding to the opening.

16. The method according to claim 15, wherein the first mold is provided on a first substrate, and the second mold is provided on a second substrate having a light transmitting property.

17. The method according to claim 6, wherein the height of the second mold is higher than the height of the first mold, and the first mold is released from the second mold.

18. The method according to claim 6, wherein the height of the first mold is higher than the height of the second mold.

19. The method according to claim 5, wherein the silicone resin is cured by ultraviolet (UV) light.
